(19) United States
(12) Patent Application Publication
(10) Pub. No.: US 2024/0321971 A1
(43) Pub. Date: Sep. 26, 2024

(54) LATERAL GALLIUM OXIDE TRANSISTOR AND METHOD OF MANUFACTURING THE SAME

(71) Applicant: POWER CUBESEMI INC., Seongnam-si (KR)

(72) Inventors: Tai Young KANG, Gwangju-si (KR); Sin Su KYOUNG, Hanam-si (KR); Yu Sup JUNG, Osan-si (KR)

(21) Appl. No.: 18/614,889

(22) Filed: Mar. 25, 2024

(30) Foreign Application Priority Data
Mar. 24, 2023 (KR) KR 10-2023-003866

(51) Int. Cl. H01L 29/24; H01L 21/02; H01L 29/40; H01L 29/417; H01L 29/423

(52) U.S. Cl. CPC H01L 29/24; H01L 21/02565; H01L 21/02631; H01L 29/401; H01L 29/41725; H01L 29/4236

(57) ABSTRACT

Lateral gallium oxide transistor disclosed. Lateral gallium oxide transistor includes a gallium oxide substrate, an n-type gallium oxide epitaxial layer epitaxially grown on the gallium oxide substrate, an insulating layer defining a gate region, a source region, and a drain region on the n-type gallium oxide epitaxial layer, a p-type nickel oxide layer deposited on the n-type gallium oxide epitaxial layer exposed in the gate region, a dielectric layer deposited on the p-type nickel oxide layer, a gate electrode layer deposited on the dielectric layer and a source electrode and a drain electrodes formed on the n-type gallium oxide epitaxial layer exposed in the source region and the drain region.

### FIELD OF INVENTION

The present invention relates to a lateral gallium oxide transistor.

### RELATED ART

Due to the rapid developments of the power, automotive electronics and home appliance industries, the demand for high-performance power semiconductor devices has exploded. Due to ongoing research, ultra-wideband semiconductors including silicon carbide and gallium nitride have achieved higher performance than silicon-based power semiconductors. However, they have the disadvantages of difficult bulk single crystal growth and high production costs.

Gallium oxide is an emerging ultra-wideband semiconductor material after silicon carbide and gallium nitride, with a bandgap of about 4.7 to about 4.9 eV, far beyond the bandgap width of silicon carbide and gallium nitride, and a theoretical breakdown field of 8 MV/cm. Gallium oxide is particularly capable of growing substrates and epitaxial layers at relatively low cost compared to other ultra-wideband semiconductor materials. However, because the effective hole mass of an appropriate p-type dopant is large and the acceptor activation energy is high, it is difficult to implement a pn homojunction-based β-Ga₂O₃ device.

### SUMMARY

There is provided a lateral gallium oxide transistor, including a gallium oxide substrate, an n-type gallium oxide epitaxial layer epitaxially grown on the gallium oxide substrate, an insulating layer defining a gate region, a source region, and a drain region on the n-type gallium oxide epitaxial layer, a p-type nickel oxide layer deposited on the n-type gallium oxide epitaxial layer exposed in the gate region, a dielectric layer deposited on the p-type nickel oxide layer, a gate electrode layer deposited on the dielectric layer and a source electrode and a drain electrodes formed on the n-type gallium oxide epitaxial layer exposed in the source region and the drain region.

In one embodiment, the n-type gallium oxide epitaxial layer includes a recessed gate trench extending inwardly in the gate region, and the p-type nickel oxide layer is deposited on the bottom of the recessed gate trench to form a pn heterojunction with the n-type gallium oxide epitaxial layer.

In one embodiment, a sidewall of the recessed gate trench has a slope of 45 degrees to 70 degrees.

In one embodiment, the dielectric layer is formed of aluminum oxide.

In one embodiment, the source and drain electrodes includes an n-type contact layer deposited on the n-type gallium oxide epitaxial layer exposed in the source region and the drain region, a first electrode layer deposited on the n-type contact layer and a second electrode layer deposited on the first electrode layer.

In one embodiment, the n-type contact layer is formed of ITO (Indium tin oxide).

There is provided a method of manufacturing lateral gallium oxide transistor, including forming an insulating layer defining a gate region, a source region, and a drain region on an n-type gallium oxide epitaxial layer epitaxially grown on an n-type gallium oxide substrate, depositing a p-type nickel oxide layer on the n-type gallium oxide epitaxial layer exposed in the gate region, depositing a dielectric layer on the p-type nickel oxide layer, depositing a gate electrode layer on the dielectric layer, and forming source and drain electrodes on the n-type gallium oxide epitaxial layer exposed in the source region and the drain region.

In one embodiment, the depositing the p-type nickel oxide layer on the n-type gallium oxide epitaxial layer exposed in the gate region includes forming a recessed gate trench by etching the n-type gallium oxide epitaxial layer in the gate region using both the insulating layer and a photoresist mask of the same pattern laminated thereon as an etch mask and depositing the p-type nickel oxide layer on the bottom surface of the recessed gate trench by sputtering a nickel oxide target in Ar—O₂ mixed gas atmosphere.

In one embodiment, the etch mask forms a sidewall slope of the recessed gate trench in the range of 45 degrees to 70 degrees.

In one embodiment, the photoresist mask forms a first trench region in the n-type gallium oxide epitaxial layer, and the insulating layer forms a second trench region having sidewalls extending from sidewalls of the first trench region.

In one embodiment, the flow rate of oxygen in the mixed gas is 9.0% to 23.0%.

In one embodiment, the flow rate of oxygen in the mixed gas is 16.6% to 23.0%.

There is provided a method of manufacturing lateral gallium oxide transistor, including forming an insulating layer defining a gate region, a source region, and a drain region on an n-type gallium oxide epitaxial layer epitaxially grown on an n-type gallium oxide substrate, forming source and drain electrodes on the n-type gallium oxide epitaxial layer exposed in the source region and the drain region, forming a recessed gate trench by etching the n-type gallium oxide epitaxial layer in the gate region using both the insulating layer and a photoresist mask of the same pattern laminated thereon as an etch mask, depositing a p-type nickel oxide layer on the bottom surface of the recessed gate trench by sputtering a nickel oxide target in Ar—O₂ mixed gas atmosphere, depositing a dielectric layer on the p-type nickel oxide layer and depositing a gate electrode layer on the dielectric layer.

According to embodiments of the present invention, a nickel oxide-gallium oxide transistor operating in accumulation mode can be manufactured.

### BRIEF DESCRIPTION OF ACCOMPANYING DRAWINGS

Hereinafter, embodiments of the invention will be described with reference to the accompanying drawings. For the purpose of easy understanding of the invention, the same elements will be referred to by the same reference signs. Configurations illustrated in the drawings are examples for describing the invention, and do not restrict the scope of the invention. Particularly, in the drawings, some elements are slightly exaggerated for the purpose of easy understanding of the invention. Since the drawings are used to easily understand the invention, it should be noted that widths, depths, and the like of elements illustrated in the drawings might change at the time of actual implementation thereof. Meanwhile, throughout the detailed description of the invention, the same components are described with reference to the same reference numerals.

FIG. 1 is a schematic cross-sectional view of a lateral gallium oxide transistor;

FIG. 2 and FIG. 3 exemplarily illustrate a process for manufacturing a lateral gallium oxide transistor;

FIG. 4 is a schematic cross-sectional view of a lateral gallium oxide transistor with recessed gate;

FIG. 5 exemplarily illustrates a process for manufacturing a lateral gallium oxide transistor with recessed gate;

FIG. 6 exemplarily illustrates another process for manufacturing a lateral gallium oxide transistor with recessed gate;

FIG. 7 exemplarily illustrates adjusting the sidewall slope of a recessed gate trench;

FIG. 8 i exemplarily illustrates the operation of a lateral gallium oxide transistor according to gate voltage;

FIG. 9 exemplarily illustrates voltage-current graph of a lateral gallium oxide transistor according to gate voltage; and

FIG. 10 is a graph illustrating the electrical characteristics of nickel oxide according to oxygen flow rate.

### DETAILED DESCRIPTION

Embodiments which will be described below with reference to the accompanying drawings can be implemented singly or in combination with other embodiments. But this is not intended to limit the present invention to a certain embodiment, and it should be understood that all changes, modifications, equivalents or replacements within the spirits and scope of the present invention are included. Especially, any of functions, features, and/or embodiments can be implemented independently or jointly with other embodiments. Accordingly, it should be noted that the scope of the invention is not limited to the embodiments illustrated in the accompanying drawings.

Terms such as first, second, etc., may be used to refer to various elements, but, these element should not be limited due to these terms. These terms will be used to distinguish one element from another element.

The terms used in the following description are intended to merely describe specific embodiments, but not intended to limit the invention. An expression of the singular number includes an expression of the plural number, so long as it is clearly read differently. The terms such as “include” and “have” are intended to indicate that features, numbers, steps, operations, elements, components, or combinations thereof used in the following description exist and it should thus be understood that the possibility of existence or addition of one or more other different features, numbers, steps, operations, elements, components, or combinations thereof is not excluded.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present.

Spatially relative terms, such as “beneath,” “below,” “lower,” “above,” “upper,” and the like, may be used herein for descriptive purposes, and, thereby, to describe one element or feature's relationship to another element(s) or feature(s) as illustrated in the drawings. Spatially relative terms are intended to encompass different orientations of an apparatus in use, operation, and/or manufacture in addition to the orientation depicted in the drawings.

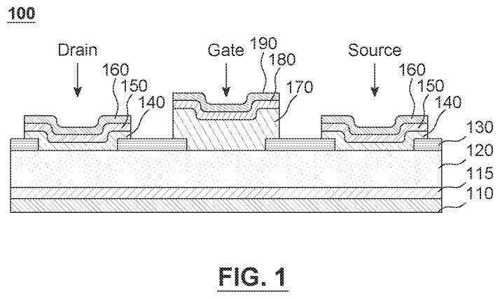

FIG. 1 is a schematic cross-sectional view of a lateral gallium oxide transistor.

Referring to FIG. 1, the lateral gallium oxide transistor 100 may include a gallium oxide substrate 110, a gallium oxide buffer layer 115, an n-type gallium oxide epitaxial layer 120, an insulating layer 130, and source/drain electrodes 140, 150, 160 and gate electrodes 170, 180, 190.

The gallium oxide substrate 110 may be formed of single crystalline β-Ga₂O₃, and the unintentionally doped (UID) gallium oxide buffer layer 115 may be formed on the electrically insulating gallium oxide substrate 110. The thickness of the gallium oxide buffer layer 115 may be about 0.2 μm.

The n-type gallium oxide epitaxial layer 120 is β-Ga₂O₃ doped with an n-type dopant epitaxially grown on the gallium oxide buffer layer 115. The n-type dopant may be, for example, silicon (Si), and the concentration of the n-type dopant may be about 2×10¹⁸ cm⁻³. The thickness of the n-type gallium oxide epitaxial layer 120 may be about 0.5 μm.

The insulating layer 130 may be formed by depositing silicon oxide (SiO₂) on the n-type gallium oxide epitaxial layer 120, and may define source/drain regions and gate regions corresponding to the source/drain electrodes and gate electrodes. The source/drain region and gate region are regions where the n-type gallium oxide epitaxial layer 120 is exposed by etching the insulating layer 130. The insulating layer 130 deposited on the n-type gallium oxide epitaxial layer 120 may function as a field plate. The thickness of the insulating layer 130 may be about 0.7 μm.

The source and drain electrodes may have the same stacked structure and may be formed in the source/drain region defined by the insulating layer 130. For example, an n-type contact layer 140 in contact with the n-type gallium oxide epitaxial layer 120 may be formed by depositing ITO (indium tin oxide), a first electrode layer 150 and a second electrode layer 160 may be formed by sequentially depositing Ti and Au. The n-type contact layer 140 may have a thickness of about 20 nm, the first electrode layer 150 may have a thickness of about 150 nm, and the second electrode layer 160 may have a thickness of about 50 nm.

The gate electrode may include a p-type nickel oxide layer 170, a dielectric layer 180, and a gate electrode layer 190 sequentially stacked in the gate area defined by the insulating layer 130. For example, the p-type nickel oxide layer 170 in contact with the n-type gallium oxide epitaxial layer 120 may be formed by depositing nickel oxide (NiOₓ), the dielectric layer 180 may be formed by depositing p-type aluminum oxide (Al₂O₃) on the p-type nickel oxide layer 170, and the gate electrode layer 190 may be formed by depositing nickel (Ni) on the dielectric layer 180. The p-type nickel oxide layer 170 may have a thickness of about 250 nm, the dielectric layer 180 may have a thickness of about 50 nm, and the gate electrode layer 190 may have a thickness of about 100 nm.

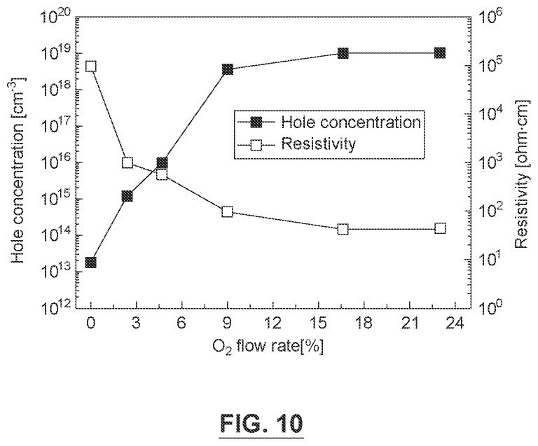

A pn heterojunction can br formed by the n-type gallium oxide epitaxial layer 120 and the p-type nickel oxide layer 170. A depletion region (see FIG. 10) may be formed in the n-type gallium oxide epitaxial layer 120 along the pn heterojunction, and the depletion region may expand or contract depending on the gate voltage. Meanwhile, the dielectric layer 180 can minimize a gate leakage current when the gate voltage increases.

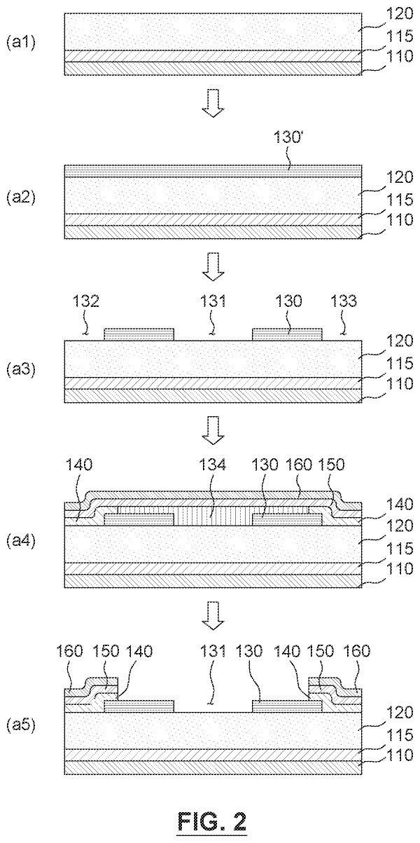

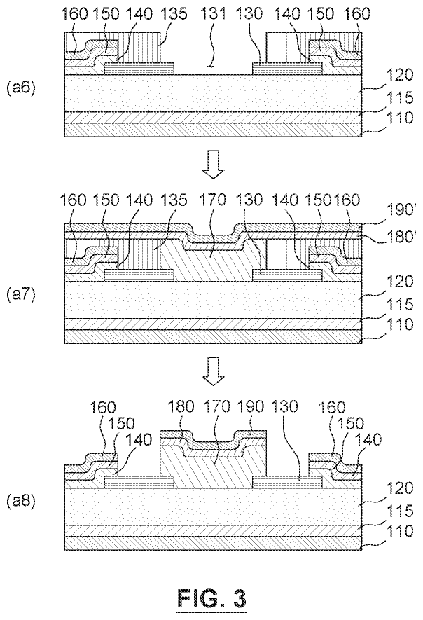

FIG. 2 and FIG. 3 exemplarily illustrate a process for manufacturing a lateral gallium oxide transistor according to one embodiment of the present invention.

In a1, an n-type gallium oxide epitaxial layer 120 is epitaxially formed on the gallium oxide buffer layer 115. Before forming the n-type gallium oxide epitaxial layer 120, foreign substances on an n-type gallium oxide substrate 110 on which a gallium oxide buffer layer 115 is formed may be removed by cleaning and plasma treatment. For example, the n-type gallium oxide epitaxial layer 120 may be formed by epitaxially growing β-Ga₂O₃ doped with silicon (Si) at a concentration of about 2×10¹⁸ cm⁻³ to a thickness of about 0.5 μm. The n-type gallium oxide epitaxial layer 120 may be formed, for example, by Halide vapor phase epitaxy (HVPE), Metalorganic chemical vapor deposition (MOCVD), Mist CVD, Molecular Beam Epitaxy (MBE), Pulsed laser deposition (PLD), etc.

In a2, a silicon oxide layer 130′ is formed on the upper surface of the n-type gallium oxide epitaxial layer 120. The silicon oxide layer 130′ may be formed by depositing SiO₂ to a thickness of about 0.7 μm by chemical vapor deposition or spin coating.

In a3, the insulating layer 130 defining the gate region 131 and source/drain regions 132 and 133 is formed by etching the silicon oxide layer 130′. In example, a photoresist layer is laminated to a thickness of approximately 1.6 μm on the upper surface of the silicon oxide layer 130′. The photoresist layer can be laminated by spin coating the photoresist on the silicon oxide layer 130′ and then soft baking it. A photoresist mask is formed by removing the photoresist in the area where the gate region 131 and source/drain regions 132 and 133 are to be formed in the photoresist layer. The insulating layer 130 is formed by etching the silicon oxide layer 130′ exposed by the photoresist mask. The etching gases are O₂ and C₄F₈ and can be supplied to the chamber at a flow rate of approximately 1:9. The chamber pressure is maintained at about 7 mTorr, and about 2 kW of power can be applied for about 1 minute. The etch rate of the silicon oxide layer 130′ may be about 0.23 μm/min. The buffer process of forming a gas atmosphere by injecting etching gas, the etching process of applying power, and the cooling process may be performed repeatedly. Then, the photoresist mask is removed.

In a4, the source/drain electrodes are formed in the source/drain regions 132 and 133. In example, a photoresist layer is laminated on the upper surface of the n-type gallium oxide epitaxial layer 120 on which the insulating layer 130 is formed. The photoresist layer formed in the source/drain regions 132 and 133 is removed, exposing the source/drain regions 132 and 133 and forming a photoresist mask 134 that covers the gate region 131. The n-type contact layer 140, the first electrode layer 150, and the second electrode layer 160 may be sequentially deposited by, for example, physical vapor deposition. Here, the n-type contact layer 140 may have a thickness of about 20 nm, the first electrode layer 150 may have a thickness of about 150 nm, and the second electrode layer 160 may have a thickness of about 50 nm.

In a5, the n-type contact layer 140, the first electrode layer 150, and the second electrode layer 160 deposited in areas other than the source/drain regions 132 and 133 are removed.

In a6, a photoresist layer is laminated on the upper surface of the n-type gallium oxide epitaxial layer 120 on which the source/drain electrodes are formed. Through a photo and etching process, the photo resist layer formed in the gate region 131 is removed to form a photo resist mask 135 with the gate region 131 exposed.

In a7, a gate electrode is formed in the gate region 131. The gate electrode may be formed by sequentially stacking the p-type nickel oxide layer 170, the dielectric layer 180, and the gate electrode layer 190 on the gate region 131.

The p-type nickel oxide layer 170 may be deposited to a thickness of about 250 nm on the upper surface of the n-type gallium oxide epitaxial layer 120 by sputtering a nickel oxide target or a nickel target. Sputtering is carried out in a mixed gas atmosphere of Ar and O₂. The flow rate of oxygen is adjusted between about 0.0% and 23.0%, preferably between about 9.0% and 16.6%, the chamber pressure is maintained at about 5 mTorr, and a power of about 150 W can be applied for about 90 minutes.

The dielectric layer 180 may be deposited to a thickness of about 50 nm on the p-type nickel oxide layer 170 by using plasma enhanced atomic layer deposition (PEALD) of Al₂O₃. The precursors are Al(CH₃)₃ and O₃, and the chuck temperature may be about 250° C.

The gate electrode layer 190 may be deposited to a thickness of about 100 nm on the dielectric layer 180 by sputtering a nickel target. Sputtering is carried out in Ar atmosphere, the chamber pressure is maintained at about 5 mTorr, and a power of about 100 W can be applied for about 8 minutes.

In a8, the p-type nickel oxide layer 170, the dielectric layer 180, and the gate electrode layer 190 deposited in areas other than the gate region 131 are removed. Afterwards, a post annealing may be performed. Post annealing is carried out at about 500° C. for about 1 minute in Ar atmosphere with a pressure of about 100 mTorr.

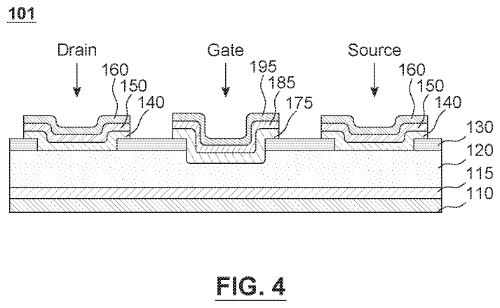

FIG. 4 is a schematic cross-sectional view of a lateral gallium oxide transistor with recessed gate.

Referring to FIG. 4, the lateral gallium oxide transistor 101 may include a gallium oxide substrate 110, a gallium oxide buffer layer 115, an n-type gallium oxide epitaxial layer 120, an insulating layer 130, and source/drain electrodes 140, 150, 160, and recessed gate electrodes 175, 185, 195. The same description as in FIG. 1 will be omitted.

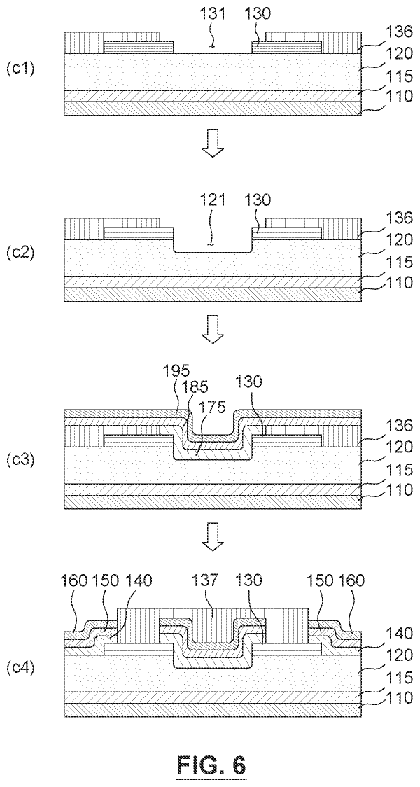

A recessed gate electrode may be formed in the recessed gate trench 121 (see FIG. 6) extending inward from the upper surface of the n-type gallium oxide epitaxial layer 120. The p-type nickel oxide layer 175 may be deposited on the bottom of the recessed gate trench 121, and may also be deposited on the sidewalls of the recessed gate trench 121 depending on the slope of the sidewalls. For example, the p-type nickel oxide layer 175 in contact with the n-type gallium oxide epitaxial layer 120 may be formed by depositing NiOₓ. The dielectric layer 185 may be formed by depositing Al₂O₃ on the p-type nickel oxide layer 175, and the gate electrode layer 195 may be formed by depositing Ni on the dielectric layer 185. The thickness of the p-type nickel oxide layer 175 stacked on the bottom of the recessed gate trench 121 may be about 250 nm, the thickness of the dielectric layer 185 may be about 50 nm, and the thickness of the gate electrode layer 195 may be about 100 nm.

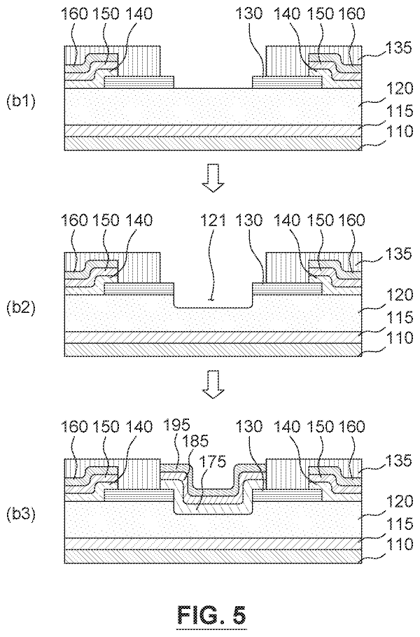

FIG. 5 exemplarily illustrates a process for manufacturing a lateral gallium oxide transistor with recessed gate.

Forming source/drain electrodes is substantially the same as a1 to a5 in FIG. 2. In b1, a photoresist layer is laminated on the upper surface of the n-type gallium oxide epitaxial layer 120 on which the source/drain is formed. Through a photo and etching process, a portion of the photoresist layer formed in the gate region 131 is removed to form a photo resist mask 135 with the gate region 131 exposed.

In b2, a recessed gate trench 121 is formed. In example, the recessed gate trench 121 may be formed by etching the n-type gallium oxide epitaxial layer 120 exposed by an etch mask toward the inside. The etch mask may be an insulating layer 130, a photoresist mask 135, or a combination thereof. The etching gases are N₂ and BCl₃, and can be supplied to the chamber at a flow rate of about 1:7. The chamber pressure is maintained at about 5 mTorr, and a power of about 500 W can be applied for about 1 minute. The etch rate of the n-type gallium oxide epitaxial layer 120 is about 0.057 μm/min, and the etch ratio between the n-type gallium oxide epitaxial layer 120 and the insulating layer 130 may be about 1:1.2. The formed recessed gate trench 121 may have a critical dimension (CD) of about 2 μm, a depth of about 0.7 μm, and a sidewall slope of about 45 degrees to about 70 degrees. The buffer process of forming a gas atmosphere by injecting etching gas, the etching process of applying power, and the cooling process may be performed repeatedly.

In b3, the gate electrode is formed in the recessed gate trench 121. The gate electrode may be formed by sequentially stacking the p-type nickel oxide layer 175, the dielectric layer 185, and the gate electrode layer 195 in the recessed gate trench 121.

The p-type nickel oxide layer 175 may be deposited to a thickness of about 250 nm on the bottom of the recessed gate trench 121 by sputtering a nickel oxide target or a nickel target. Meanwhile, the p-type nickel oxide layer 175 may also be deposited on the sidewall of the recessed gate trench 121 according to the slope of the sidewall. Sputtering is carried out in a mixed gas atmosphere of Ar and O₂. The flow rate of oxygen is adjusted between about 0.0% and 23.0%, preferably between about 9.0% and 16.6%, the chamber pressure is maintained at about 5 mTorr, and a power of about 150 W can be applied for about 90 minutes.

The dielectric layer 185 may be deposited to a thickness of about 50 nm on the p-type nickel oxide layer 175 by using plasma enhanced atomic layer deposition (PEALD) of Al₂O₃. The precursors are Al(CH₃)₃ and O₃, and the chuck temperature may be about 250° C. Meanwhile, the dielectric layer 185 may also be deposited on the p-type nickel oxide layer 175 deposited on the sidewall of the recessed gate trench 121 according to the slope of the sidewall.

The gate electrode layer 195 may be deposited to a thickness of about 100 nm on the dielectric layer 185 by sputtering a nickel target. Sputtering is carried out in Ar atmosphere, the chamber pressure is maintained at about 5 mTorr, and a power of about 100 W can be applied for about 8 minutes.

The p-type nickel oxide layer 175, dielectric layer 185, and gate electrode layer 195 deposited in areas other than the recessed gate trench 121 or the gate region 131 are removed. Then, the post annealing process may be performed.

FIG. 6 exemplarily illustrates another process for manufacturing a lateral gallium oxide transistor with recessed gate.

Forming the insulating layer 130 is substantially the same as a1 to a3 in FIG. 2. In c1, a photoresist mask 136 is stacked to expose the gate region 131 and cover the source/drain regions 132 and 133.

In c2, the n-type gallium oxide epitaxial layer 120 exposed by the etch mask is etched inward to form a recessed gate trench 121. The etch mask may be an insulating layer 130, the photoresist mask 136, or a combination thereof.

In c3, the gate electrode is formed by sequentially stacking the p-type nickel oxide layer 175, the dielectric layer 185, and the gate electrode layer 195 on the recessed gate trench 121, and by removing the p-type nickel oxide layer 175, dielectric layer 185, and gate electrode layer 195 deposited in areas other than the recessed gate trench 121 and the region 131.

In c4, source/drain electrodes are formed in the source/drain regions 132 and 133. Forming source/drain electrodes is substantially the same as a1 to a5 in FIG. 2. Once the source/drain electrodes are formed, the post annealing process can be performed.

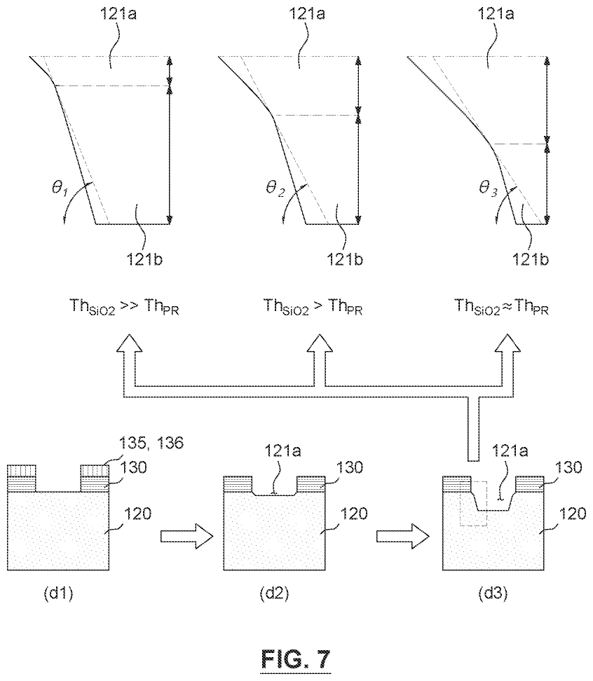

FIG. 7 exemplarily illustrates adjusting the sidewall slope of a recessed gate trench.

In d1, an etch mask is formed by etching the silicon oxide layer 130′ exposed by the photoresist mask 140.

In d2, the first trench region 121a is formed by etching the n-type gallium oxide epitaxial layer 120 exposed by the insulating layer 130 and the photoresist mask 140 laminated on the insulating layer 130. The first trench region 121a is formed by the photoresist mask 140. Since the photoresist mask 140 is also etched at a constant rate, the thickness of the photoresist mask 140 can be adjusted according to the depth of the first trench region 121a.

In d3, a second trench region 121b having sidewalls extending from the sidewalls of the first trench region 121a is formed with the insulating layer 130. The first trench region 121a and the second trench region 121b form the recessed gate trench 121.

The etch mask used to etch the recessed gate trench 121 may be selected from (i) the insulating layer 130 formed of silicon oxide, (ii) the photoresist masks 135, 136, or (iii) the insulating layer 130 and the photoresist masks 135, 136 of the same pattern laminated on top of the insulating layer 130. The sidewall slope of the recessed gate trench 121 may be adjusted depending on the type of etch mask. If the n-type gallium oxide epitaxial layer 120 is etched using only the insulating layer 130, the sidewall slope of the recessed gate trench 121 may be about 70 degrees. If the n-type gallium oxide epitaxial layer 120 is etched using only the photoresist masks 135, 136, the sidewall slope of the recessed gate trench 121 may be about 45 degrees.

The sidewall slope from the top to the bottom of the first trench region 121a may be determined by the thickness of the photoresist masks 135, 136, and the sidewall slope of the second trench region 121b may be determined by the combination of the side wall slope of the first trench region 121a and the insulating layer 130. Accordingly, when the insulating layer 130 and the photoresist masks 135, 136 of the same pattern stacked on top of the insulating layer 130 are used as the etch mask, the sidewall slope of the recessed gate trench 121 can be adjusted in about 45 degrees and about 70 degrees.

FIG. 7 illustrates the slope of the sidewall of the recessed gate trench when the thickness of the photoresist masks 135, 136 is increased while maintaining the sum of the thickness of the photoresist masks 135, 136 and the thickness of the insulating layer 130. The first trench region 121a formed by the photoresist masks 135, 136 has sidewalls inclined at about 45 degrees due to the polymer generated by the photoresist. As the thickness of the photoresist increases, the depth of the first trench region 121a becomes deeper, and the depth of the second trench region 121b becomes shallower. When etching using the photoresist masks 135, 136 is completed, then etching using the insulating layer 130 begins. During the etching process of the insulating layer 130, the sidewall inclined at about 45 degrees due to the polymer is also etched downwardly. As a result, the sidewall of the recessed gate trench 111 becomes closer to a curved surface as a whole. Therefore, the side wall slopes θ1, θ2, and θ3 can be measured using the tangent line touching the curved surface. When the photoresist masks 135, 136 have the thinnest thickness, the sidewall slope θ₁ approaches approximately 70 degrees, and when the insulating layer 130 has the thinnest thickness, the sidewall slope θ₃ approaches approximately 45 degrees.

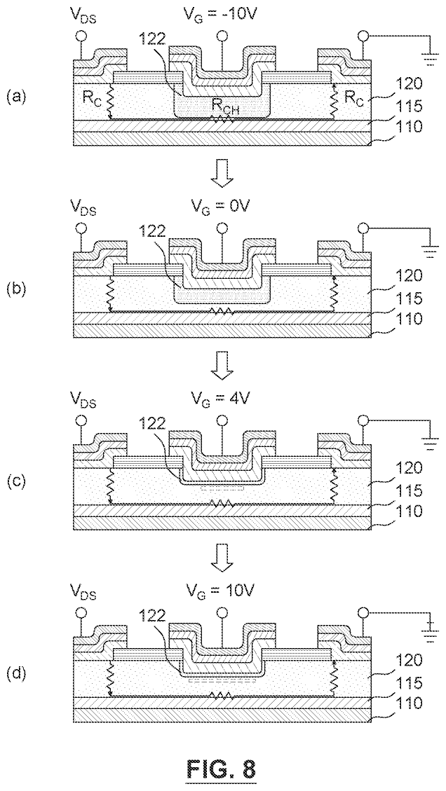

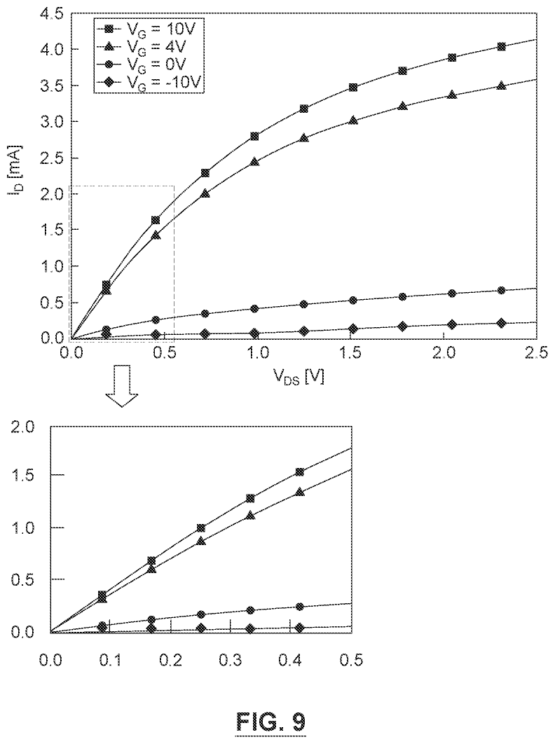

FIG. 8 i exemplarily illustrates the operation of a lateral gallium oxide transistor according to gate voltage, and FIG. 9 exemplarily illustrates voltage-current graph of a lateral gallium oxide transistor according to gate voltage.

Referring to FIG. 8 and FIG. 9 together, the total resistance Rₜₒₜₐₗ between the drain and the source is the sum of the source/drain contact resistance 2R_{c} and the channel resistance R_{ch}. The source/drain contact resistance 2R_{c} is constant at about 0.02 kΩ and is not affected by the depletion region 122. On the other hand, the channel resistance R_{ch} is affected by the depletion region (Intrinsic depletion region 122). Table 1 shows the channel resistance R_{ch} measured by applying a voltage to a recessed gate with a lateral width of approximately 5 μm.

TABLE 1

| V_{G}(V) | −10 | 0 | 4 | 10 |
|---|---|---|---|---|
| Rₜₒₜₐₗ(kΩ) | 10.48 | 3.56 | 0.718 | 0.623 |
| R_{ch}(kΩ) | 10.46 | 3.54 | 0.698 | 0.603 |

When the gate voltage V_{G} is between about −10V and 0V, the channel resistance R_{ch} is about 10.46 kΩ to about 3.54 kΩ. This indicates that the lateral gallium oxide transistor is normally off. The channel is formed in the n-type gallium oxide epitaxial layer 120 under the gate, and may be blocked or conducted by the depletion region 122 formed in the n-type gallium oxide epitaxial layer 120 by pn heterojunction. The depletion region 122 expands or contracts depending on the gate voltage V_{G}.

When the gate voltage V_{G} is between about 0V and 4V, the channel resistance R_{ch} is about 3.54 kΩ to 0.698 kΩ. This indicates that the lateral gallium oxide transistor turns on when a gate voltage V_{G} of 0V or more is applied. It can be seen that an ohmic region is formed until the drain-source voltage V_{DS} is about 0.5V, and from 0.5V or higher, electrons are accumulated in the channel due to an increase in gate voltage V_{G}.

FIG. 10 is a graph illustrating the electrical characteristics of nickel oxide according to oxygen flow rate.

The hole concentration and resistivity of p-type nickel oxide can be adjusted depending on the oxygen flow rate during deposition. FIG. 10 shows the hole concentration and resistivity of the p-type nickel oxide layer deposited while adjusting the oxygen flow rate in Ar—O₂ mixed gas to about 0.0%, about 2.4%, about 4.7%, about 9.0%, about 16.6%, and about 23.0%, and Table 2 shows the process parameters and measured breakdown voltage according to each oxygen flow rate.

TABLE 2

| | O₂ flow rate | | | | | |
|---|---|---|---|---|---|---|
| | 0.0% | 2.4% | 4.7% | 9.0% | 16.6% | 23.0% |
| process time | 37 | 66 | 85 | 89 | 90 | 92 |
| (Minutes) | | | | | | |
| Deposition | 8.1 | 4.5 | 3.5 | 3.4 | 3.3 | 3.2 |
| rate (nm/min) | | | | | | |
| Hole | 1.8 × 10¹³ | 1.2 × 10¹⁵ | 1.0 × 10¹⁶ | 3.7 × 10¹⁸ | 1.05 × 10¹⁹ | 1.03 × 10¹⁹ |
| concentration | | | | | | |
| (cm⁻³) | | | | | | |
| Resistivity | 98,400 | 994 | 564 | 96 | 42 | 44 |
| (ohm · cm) | | | | | | |

Referring to FIG. 10, as the oxygen flow rate increases, the hole concentration increases while the resistivity decreases. The hole concentration in the oxygen flow rate range of about 9.0% to about 23.0% is significantly increased over the hole concentration in the oxygen flow rate range of about 0.0% to about 4.7%, and the resistivity in the oxygen flow rate range of about 16.6% to about 23.0% is significantly decreased over the resistivity in the oxygen flow rate range of about 0.0% to about 9.0%. Therefore, the oxygen flow rate can be adjusted in the range of about 9.0% to about 23.0%, and preferably in the range of about 16.6% to about 23.0%.

The above description of the invention is exemplary, and those skilled in the art can understand that the invention can be modified in other forms without changing the technical concept or the essential feature of the invention. Therefore, it should be understood that the above-mentioned embodiments are exemplary in all respects, but are not definitive.

The scope of the invention is defined by the appended claims, not by the above detailed description, and it should be construed that all changes or modifications derived from the meanings and scope of the claims and equivalent concepts thereof are included in the scope of the invention.

What is claimed is:

1. A lateral gallium oxide transistor, comprising:
a gallium oxide substrate;
an n-type gallium oxide epitaxial layer epitaxially grown on the gallium oxide substrate;
an insulating layer defining a gate region, a source region, and a drain region on the n-type gallium oxide epitaxial layer;
a p-type nickel oxide layer deposited on the n-type gallium oxide epitaxial layer exposed in the gate region;
a dielectric layer deposited on the p-type nickel oxide layer;
a gate electrode layer deposited on the dielectric layer; and
a source electrode and a drain electrodes formed on the n-type gallium oxide epitaxial layer exposed in the source region and the drain region.

2. The lateral gallium oxide transistor of claim 1, wherein the n-type gallium oxide epitaxial layer comprises a recessed gate trench extending inwardly in the gate region,
wherein the p-type nickel oxide layer is deposited on the bottom of the recessed gate trench to form a pn heterojunction with the n-type gallium oxide epitaxial layer.

3. The lateral gallium oxide transistor of claim 2, wherein a sidewall of the recessed gate trench has a slope of 45 degrees to 70 degrees.

4. The lateral gallium oxide transistor of claim 1, wherein the dielectric layer is formed of aluminum oxide.

5. The lateral gallium oxide transistor of claim 1, wherein the source and drain electrodes comprises:
an n-type contact layer deposited on the n-type gallium oxide epitaxial layer exposed in the source region and the drain region;
a first electrode layer deposited on the n-type contact layer; and
a second electrode layer deposited on the first electrode layer.

6. The lateral gallium oxide transistor of claim 5, wherein the n-type contact layer is formed of ITO (Indium tin oxide).

7. A method of manufacturing lateral gallium oxide transistor, comprising:
forming an insulating layer defining a gate region, a source region, and a drain region on an n-type gallium oxide epitaxial layer epitaxially grown on an n-type gallium oxide substrate;
depositing a p-type nickel oxide layer on the n-type gallium oxide epitaxial layer exposed in the gate region;
depositing a dielectric layer on the p-type nickel oxide layer;
depositing a gate electrode layer on the dielectric layer; and
forming source and drain electrodes on the n-type gallium oxide epitaxial layer exposed in the source region and the drain region.

8. The method of claim 7, wherein the depositing the p-type nickel oxide layer on the n-type gallium oxide epitaxial layer exposed in the gate region comprises:
forming a recessed gate trench by etching the n-type gallium oxide epitaxial layer in the gate region using both the insulating layer and a photoresist mask of the same pattern laminated thereon as an etch mask; and
depositing the p-type nickel oxide layer on the bottom surface of the recessed gate trench by sputtering a nickel oxide target in Ar—O₂ mixed gas atmosphere.

9. The method of claim 8, wherein the etch mask forms a sidewall slope of the recessed gate trench in the range of 45 degrees to 70 degrees.

10. The method of claim 9, wherein the photoresist mask forms a first trench region in the n-type gallium oxide epitaxial layer, and the insulating layer forms a second trench region having sidewalls extending from sidewalls of the first trench region.

11. The method of claim 8, wherein the flow rate of oxygen in the mixed gas is 9.0% to 23.0%.

12. The method of claim 11, wherein the flow rate of oxygen in the mixed gas is 16.6% to 23.0%.

13. A method of manufacturing lateral gallium oxide transistor, comprising:
forming an insulating layer defining a gate region, a source region, and a drain region on an n-type gallium oxide epitaxial layer epitaxially grown on an n-type gallium oxide substrate;
forming source and drain electrodes on the n-type gallium oxide epitaxial layer exposed in the source region and the drain region;
forming a recessed gate trench by etching the n-type gallium oxide epitaxial layer in the gate region using both the insulating layer and a photoresist mask of the same pattern laminated thereon as an etch mask;
depositing a p-type nickel oxide layer on the bottom surface of the recessed gate trench by sputtering a nickel oxide target in Ar—O₂ mixed gas atmosphere;
depositing a dielectric layer on the p-type nickel oxide layer; and
depositing a gate electrode layer on the dielectric layer.

14. The method of claim 13, wherein the etch mask forms a sidewall slope of the recessed gate trench in the range of 45 degrees to 70 degrees.

15. The method of claim 13, wherein the photoresist mask forms a first trench region in the n-type gallium oxide epitaxial layer, and the insulating layer forms a second trench region having sidewalls extending from sidewalls of the first trench region.

16. The method of claim 15, wherein the flow rate of oxygen in the mixed gas is 9.0% to 23.0%.

17. The method of claim 16, wherein the flow rate of oxygen in the mixed gas is 16.6% to 23.0%.
